(19) United States
(12) Patent Application Publication
(10) Pub. No.: US 2012/0113087 A1
(43) Pub. Date: May 10, 2012

(54) CURRENT-DRIVEN-PIXEL CIRCUITS AND RELATED METHODS

(76) Inventors: Carl P. Taussig, Palo Alto, CA (US); Richard E. Elder, Palo Alto, CA (US); Warren Jackson, Palo Alto, CA (US); Hao Luo, Palo Alto, CA (US)

(21) Appl. No.: 13/377,804

(22) PCT Filed: Jun. 18, 2009
(86) PCT No.: PCT/US09/47775

§ 371 Date: Dec. 12, 2011

(51) Int. Cl. G09G 3/32; G09G 5/00; H01L 21/02

(52) U.S. Cl. 345/212; 438/381; 345/76; 257/E21.008

(57) ABSTRACT

Pixel circuits (100, 300) and related methods are provided. In this regard, a representative pixel circuit includes: a data line (104, 304) operative to carry a data signal; a select line (106, 306) operative to carry a select signal; a first thin film transistor (TFT) (T1, T1A) conductively coupled to the data line and to the select line; and a second TFT (T2, T2A) capacitively coupled to the first TFT, the second TFT being operative to drive an emissive load responsive to the data signal and the select signal; wherein the data signal is provided to the second TFT through capacitive coupling.

### BACKGROUND

1. Technical Field

This disclosure relates to the field of semiconductor devices and fabrication.

2. Description of the Related Art

Active matrix backplanes that are used to control light emitting diode (LED) pixels of display devices, for example, oftentimes involve driving and/or sensing currents. Since these backplanes typically incorporate thin film transistors (TFTs), routing of the driving and/or sensing currents usually requires electrical connections between the sources and drains of some TFTs with the gates of others. Notably, since the sources and drains are often located on different metal layers than the metal layer on which the gates are located, vias (electrical connections formed through the layers) are conventionally used to facilitate the routing of the currents. Unfortunately, vias tend to increase production costs as their formation typically involves dedicated processing steps requiring relatively high precision.

### BRIEF DESCRIPTION OF THE DRAWINGS

Many aspects of the disclosure can be better understood with reference to the following drawings. The components in the drawings are not necessarily to scale. Moreover, in the drawings, like reference numerals designate corresponding parts throughout the several views.

FIG. 1 is a circuit diagram depicting an exemplary embodiment of a persistent current pixel circuit.

FIGS. 2A and 2B are schematic diagrams depicting an exemplary embodiment of a display device active matrix and a pixel circuit corresponding to the diagram of FIG. 1.

FIG. 3 is a cross-section of the embodiment of FIG. 2, as viewed along line 3-3, and showing detail of a capacitor.

FIG. 4 is a cross-section of the embodiment of FIG. 2, as viewed along line 4-4, and showing detail of a transistor.

FIG. 5 is a flowchart depicting method steps of an exemplary embodiment of a process for forming a semiconductor device.

FIG. 6 is a schematic diagram depicting a cross-section of a substrate and material layers involved with an intermediate process step from FIG. 5.

FIGS. 7A-D are schematic diagrams depicting cross-sections of a substrate, material layers and a 3D resist involved with the process of FIG. 5.

FIG. 8 is a circuit diagram depicting another exemplary embodiment of a persistent current pixel.

### DETAILED DESCRIPTION

Pixel circuits and related methods are provided, several exemplary embodiments of which will be described in detail. In some embodiments, a pixel circuit is provided that uses capacitive coupling to provide a persistent current for driving an emissive load in contrast to using a via. The use of capacitive coupling allows the pixel circuit to avoid the need for a via and, as such, efficiencies in fabrication may be achieved. Since the pixel circuit does not require a via, fabrication can be accomplished using, for example, a Self-Aligned Imprint Lithography (SAIL) process that can utilize roll-to-roll (R2R) manufacturing. For more information on SAIL processes, please refer to U.S. Pat. No. 7,202,719, for example, which is incorporated by reference herein. Notably, as used herein, the term “persistent current” refers to a substantially constant current (such as can be used for driving and/or sensing) provided between data updates to a pixel.

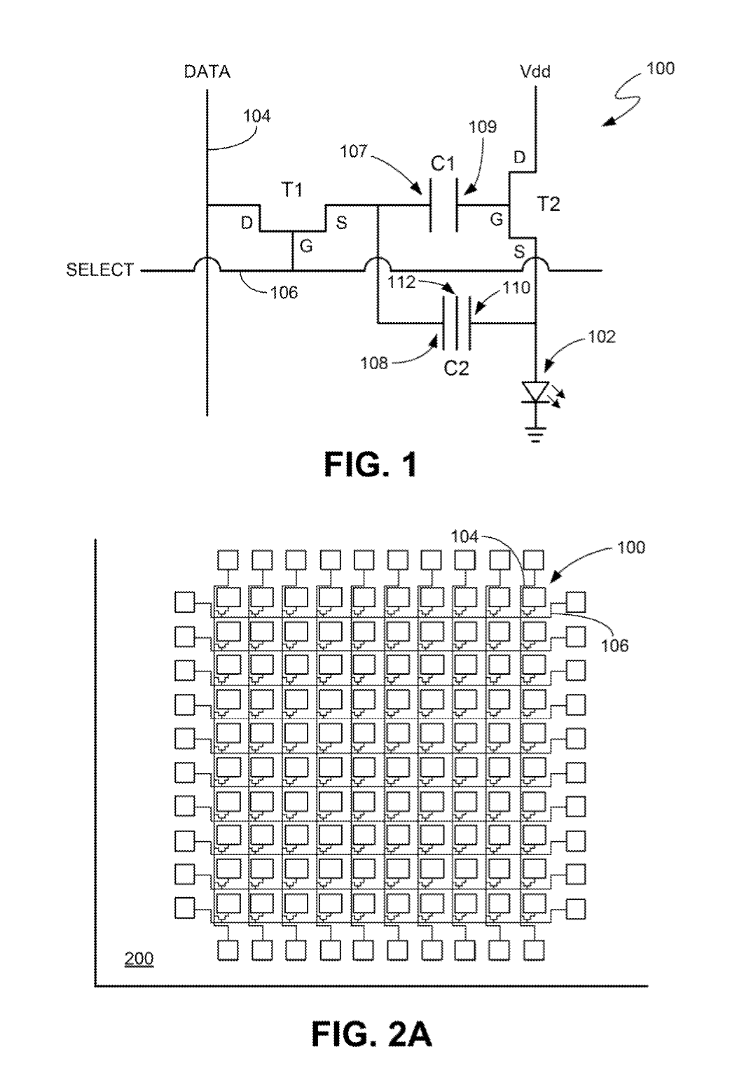

In this regard, reference is made to FIG. 1, which depicts an exemplary embodiment of a persistent current pixel circuit. As shown in FIG. 1, pixel circuit 100 includes thin film transistors (TFT's) T1 and T2, capacitors C1 and C2, and an emissive load 102. In this embodiment, emissive load 102 is a light emitting diode (LED), e.g., an organic LED or “OLED”.

TFT T1 is conductively coupled to a data line 104 and to a select line 106. Specifically, data line 104 is conductively coupled to drain electrode (D) of TFT T1, and select line 106 is conductively coupled to gate electrode (G) of TFT T1. The source electrode (S) of TFT T1 is conductively coupled to electrodes 107, 108 of capacitors C1 and C2, respectively.

TFT T2 is capacitively coupled to TFT T1. In this embodiment, the capacitive coupling is facilitated by electrode 109 of capacitor C1 being conductively coupled to gate electrode (G) of TFT T2, and electrode 110 of capacitor C2 being conductively coupled to source electrode (S) of TFT T2. Capacitor C2 of this embodiment includes an electrically floating electrode 112. Notably, use of a floating electrode configuration positions both terminals (i.e., electrodes 108 and 110) at the top metal layer, which constitutes source/drain material. In contrast, for a typical non-floating electrode configuration, a via would likely be used to conductively couple a terminal of the capacitor to the bottom metal layer. This is because such a non-floating electrode configuration would conventionally use the gate dielectric as the capacitor dielectric.

Additionally, drain electrode (D) of TFT T2 is conductively coupled to V_{dd}, and source electrode (S) of TFT T2 is conductively coupled to emissive load 102. Notably, circuit 100 lacks a via for electrically connecting a data signal, which is provided by data line 104, to TFT T2.

In operation, emissive load 102 is driven responsive to the data signal and the select signal provided by the data and select lines, respectively. Specifically, at each frame cycle, data is transferred to the circuit by the data line to TFT T1 as enabled by a select signal provided during an active mode of the select line. Notably, the select line selectively exhibits either an active or inactive mode, with the active mode for this embodiment for the frame cycle time divided by the number of gate lines.

Responsive to the select signal, the transferred data is stored by capacitor C2, which functions as a hold capacitor. The hold capacitor C2 drives TFT T2, which provides a persistent current to the emissive load. Notably, this is accomplished without a conductive coupling for controlling TFT T2, i.e., TFT T2 is controlled through capacitive coupling.

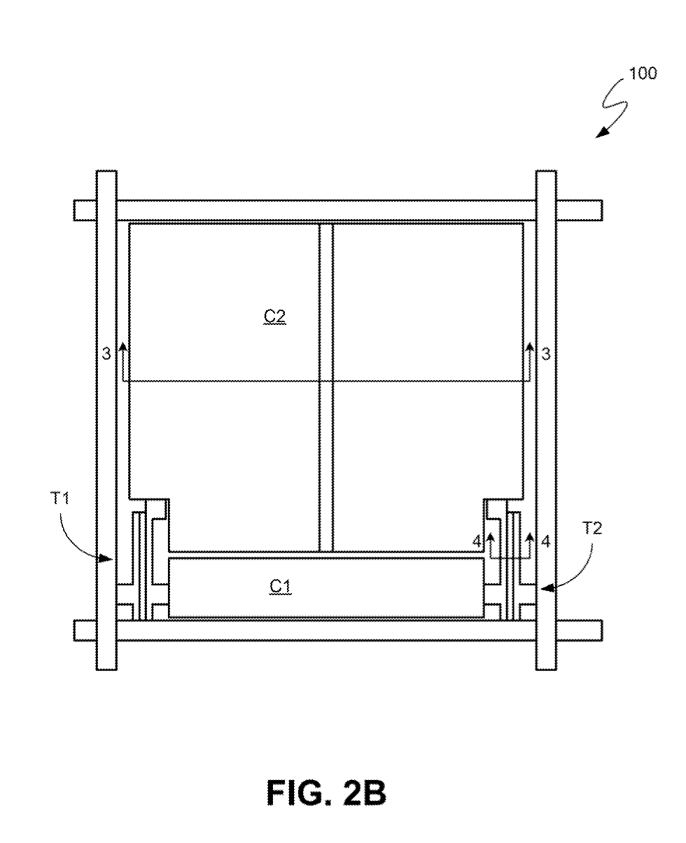

FIGS. 2A and 2B are schematic diagrams depicting an exemplary embodiment of a display device active matrix and a pixel circuit corresponding to the diagram of FIG. 1. Please note the correspondence between the reference numbers of FIGS. 1, 2A and 2B that has been retained for ease of description.

As shown in FIG. 2A, display device 200 (which may be configured for use with various electronic devices, such as cell phones, laptop computers, etc.) includes an active matrix of pixel circuits, of which pixel circuit 100 is one. Pixel circuit 100 (which is shown in greater detail in FIG. 2B) includes TFT's T1 and T2, capacitors C1 and C2, and an emissive load (not shown).

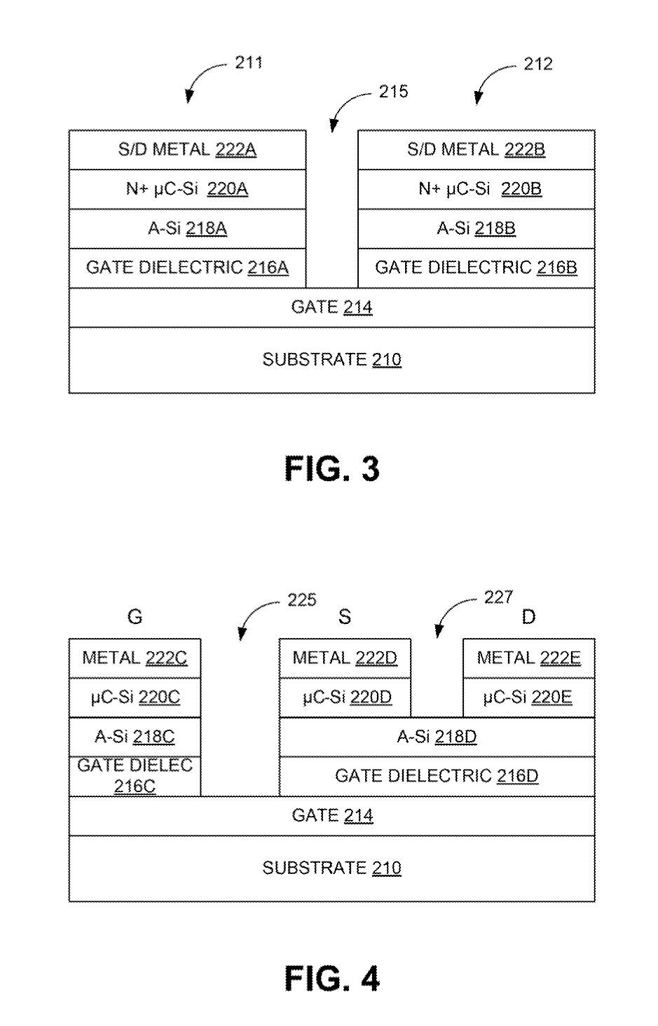

FIG. 3 is a cross-section of the embodiment of pixel circuit 100 of FIG. 2B, as viewed along line 3-3, and showing detail of capacitor C2. As shown in FIG. 3, capacitor C2 is formed by material layers supported by a substrate 210. In particular, capacitor C2 includes first and second capacitor portions 211, 212 that are formed on a shared gate layer 214, which functions as the floating electrode (e.g., floating electrode 112 of FIG. 1). Above gate layer 214, portions 211, 212 are spaced from each other by a gap 215 that separates the capacitor terminals.

In addition to the gate layer, portion 211 of capacitor C2 includes a gate dielectric layer 216A, an amorphous silicon layer 218A, a doped (N+) microcrystalline silicon layer 220A and a metal layer 222A, which functions as an electrode (e.g., electrode 108 of FIG. 1). With respect to portion 212, that portion of capacitor C2 includes a gate dielectric layer 2166, an amorphous silicon layer 218B, a doped (N+) microcrystalline silicon layer 220B and a metal layer 222B, which functions as an electrode (e.g., electrode 110 of FIG. 1).

It should be noted that, in some embodiments, as the voltage at the bottom of the capacitor (e.g., gate layer 214) is increased relative to the top (e.g., metal layer 222), charge accumulates at the semiconductor dielectric interface (i.e., the interface between layers 218 and 220) resulting in increased capacitance, which should not have a significant effect on operation. Additionally, a leaky or shorted dielectric on the driven side of the device (i.e., between electrode 107 of capacitor C1 and gate (G) of TFT T2) could improve device performance by functioning as a conductive coupling.

Although particular families of materials may have been set forth above for forming the layers, various materials may be used. In this regard, conductive layers can be metals. Commonly used metals, include, but are not limited to, Al, Mo, Cr, Cu, Ti, Ni. Additionally, since conductors are often required to be transparent in display applications, conductive oxides such as ITO (Indium Tin Oxide) and doped zinc oxide, for example, can be used. Alternatively, pixel electrodes are sometimes made from organic materials such as PEDOT (Polyethylenedioxythiophene), for example.

Semiconductors can be inorganic (e.g., amorphous silicon or polysilicon) or can be transition metal oxides (e.g., zinc indium oxide, zinc tin oxide, indium gallium zinc oxide). Organic semiconductors can be either small molecules (e.g., pentacene) or polymers (e.g., polyacetylene).

Dielectrics can also be organic or inorganic. Examples of the latter are silicon nitride and silicon dioxide as well as other oxides and nitrides such as hafnium oxide. Organic dielectrics are often very particular to the organic semiconductor they are paired with. For instance, benzocyclobutane is often used with pentacene.

Equations for predicting the voltages, charges and capacitances for the electrodes of capacitor C2 are presented below, in which it is assumed that ideal dielectrics (i.e., dielectrics exhibiting no leakage and no charge trapping) are used under DC conditions. In the equations:
A₁ is the area of electrode 110;
A₂ is the area of electrode 108;
d₁ is the distance between electrode 108 and floating electrode 112;
d₂ is the distance between electrode 110 and floating electrode 112;
q₁ is the charge on electrode 110;
q₂ is the charge of electrode 108;
V is the source voltage; and
Vₘ is the voltage of the floating electrode 112.
   Given equation 1 of:

Vm/V=(A1/A2)/((A1/A2)+(d1/d2));
if d1=d2 and A1>>A2, then Vm/V≈1;
if d1=d2 and A1<<A2, then Vm/V≈0; and
if d1=d2 and A1=A2, then Vm/V≈½.
   Additionally, given equation 2 of:

CΔ=q/V=ε(A₁A₂)/((d₁A₂)+(d₂A₁));

Therefore, for constant total area A=A₁+A₂ and d1=d2,

dC/dA₁=(ε/Ad)(A−2A₁), and

C is maximum at A₁=A/2. That is, for a fixed area, the maximum capacitance is predicted when the area of the dielectric is the same on both sides of the floating electrode 112 of capacitor C2. Additionally, maximum voltage transfer to the gate (G) of TFT T2 occurs when the area of the dielectric on the opposite side of the floating electrode from TFT T2 is much larger than the area of the gate dielectric.

FIG. 4 is a cross-section of the embodiment of FIG. 2, as viewed along line 4-4, and showing detail of a TFT. As shown in FIG. 4, TFT T2 is formed by material layers supported by a substrate; in this case, substrate 210. In particular, TFT T2 includes a gate (G), a source (S) and a drain (D) that are formed on shared gate layer 214. Above gate layer 214, gate (G) is spaced from source (S) by a gap 225.

In addition to the gate layer, gate (G) of TFT T2 includes a gate dielectric layer 216C, an amorphous silicon layer 218C, a doped (N+) microcrystalline silicon layer 220C and a metal layer 222C. Metal layer 222C functions as the gate electrode of TFT T2.

Source (S) and drain (D) share gate dielectric layer 216D and amorphous silicon layer 218D, above which the source and drain are separated by a gap 227. Above amorphous silicon layer 218D, the source includes a doped (N+) microcrystalline silicon layer 220D and a metal layer 222D, which functions as the source electrode, whereas the drain includes a doped (N+) microcrystalline silicon layer 220E and a metal layer 222E. Metal layer 222E functions as the drain electrode of TFT T2.

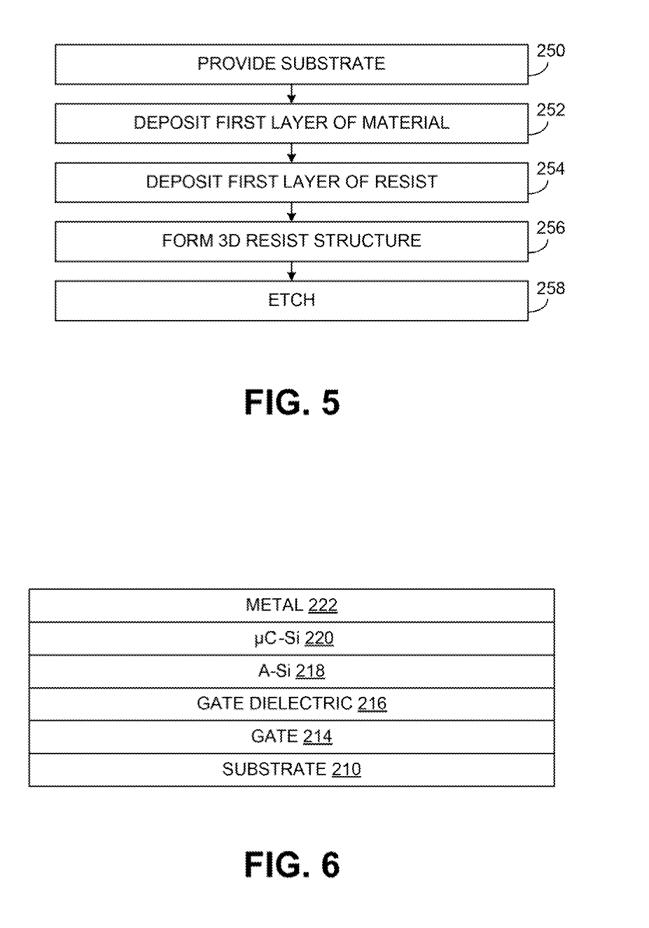

It should be noted that the vertical symmetry exhibited by the material layers of the capacitor and TFT lends itself well to fabrication by a SAIL process, a representative example of which will be described in more detail with respect to FIGS. 5-7.

In this regard, FIG. 5 is a flowchart depicting method steps of an exemplary embodiment of a SAIL process for forming a semiconductor device, such as a device including a persistent current pixel circuit. As shown in FIG. 5, the process may be construed as beginning at block 250, in which a substrate is provided. In block 252, a first layer of material is deposited over the substrate. In some embodiments, the first layer is one of multiple material layers that are supported by the substrate to form a stack of layers. For instance, FIG. 6 is a schematic diagram depicting a cross-section of a substrate with material layers deposited thereon to form a stack of material layers.

In FIG. 6, substrate 210 supports a stack of material layers that includes a gate layer 214, a gate dielectric layer 216, an amorphous silicon layer 218, a doped (N+) microcrystalline silicon layer 220 and a metal layer 222. These layers can be used to form one or more of the capacitors and TFT's, for example, of a pixel circuit. Notably, the first layer of material mentioned in block 252 may be any of the layers supported by substrate 210.

In block 254 (FIG. 5), a first layer of resist is deposited over the substrate, such as over the first layer of material. In block 256, the first layer of resist is used to form a 3D resist structure over the substrate.

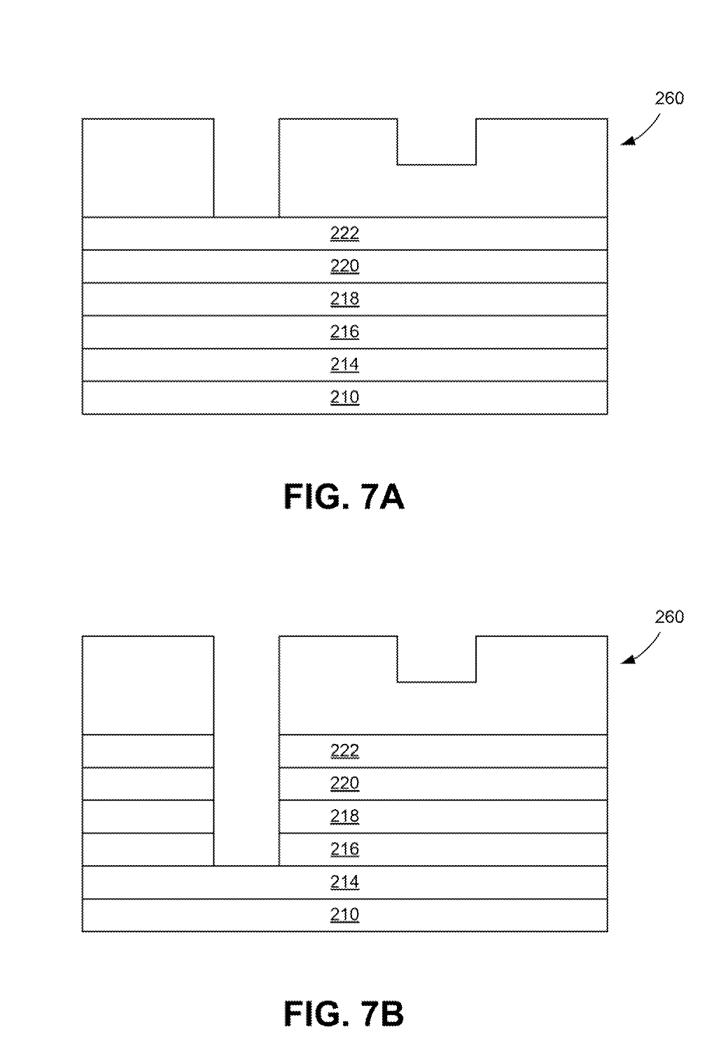

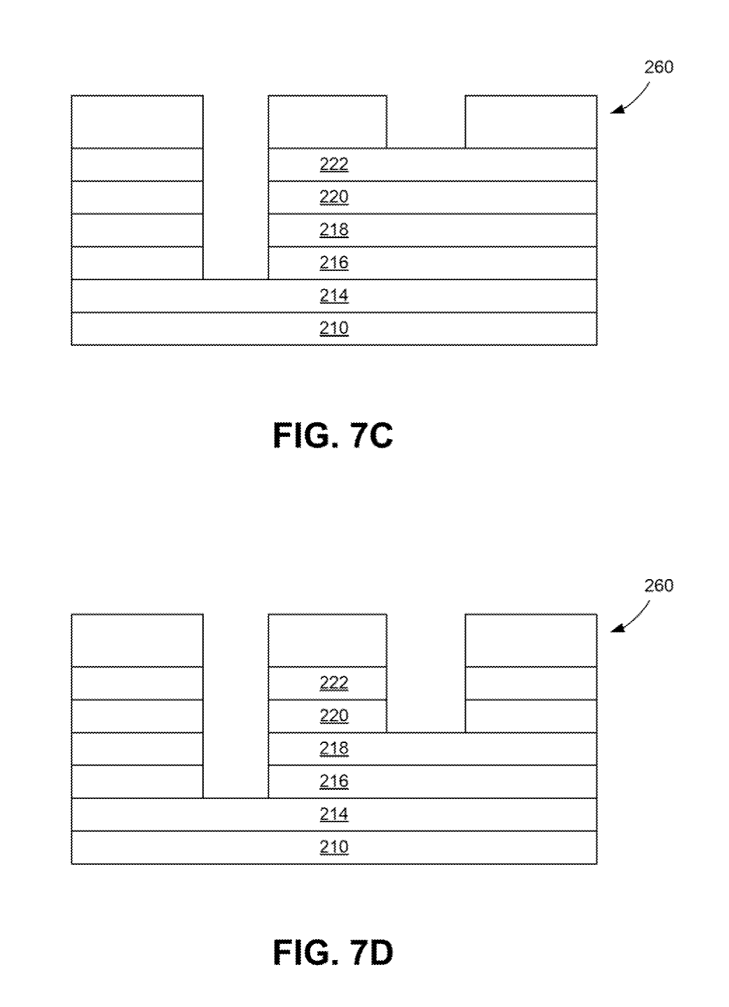

By way of example, FIG. 7A is a schematic diagram depicting a cross-section of substrate 210, material layers 214, 216, 218, 220 and 222, and a 3D resist structure 260. In the embodiment of FIG. 7, 3D resist structure 260 is configured for forming a portion of a semiconductor device (e.g., a portion of TFT T2).

As depicted in block 258 of FIG. 5, the 3D resist structure is etched to expose a first portion of the first layer of material such that the first portion forms part of a first semiconductor device. In this regard, FIGS. 7B and 7C depict sequential intermediate steps during the etching, with the configuration after etching being shown in FIG. 7D. By way of example, the first exposed portion could form electrodes of TFT T2 of FIG. 4.

It should be noted that in a SAIL process, a stack of thin films is typically deposited before any patterning is performed. This results in each layer being substantially planar and parallel with other layers of the stack. In contrast, with conventional thin film processing (e.g., photolithography), the layers are deposited on top of previously patterned layers, which can lead to step coverage problems and non-uniform film thicknesses and electrical stress concentrations. Notably, by providing a SAIL fabrication without using vias, at least one masking step and one etching step are eliminated compared to conventional photolithographic fabrication techniques.

Additionally, by utilizing a SAIL process, such as the embodiment described above, for example, the problem of multiple alignments on flexible (mechanically unstable) substrates can be addresses. Notably, plastic substrates are known to exhibit process induced distortions on the order of 1000 ppm. These distortions can lead to significant alignments on large area backplanes. SAIL addresses this issue by performing potentially all of the masking steps in a single imprint. In some embodiments, the 3D imprinted mask distorts with the substrate to maintain alignment regardless of process induced distortion.

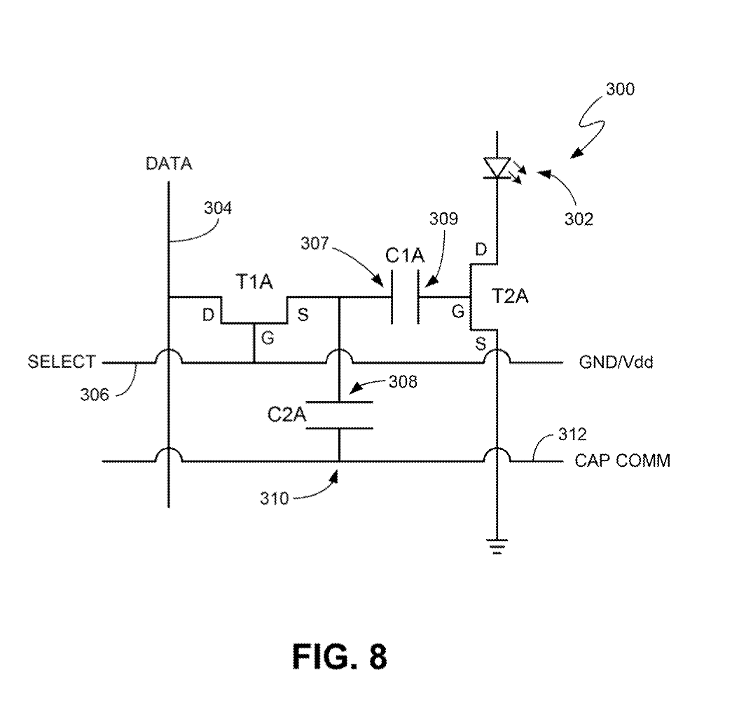

FIG. 8 is a circuit diagram depicting another exemplary embodiment of a persistent current pixel. As shown in FIG. 8, pixel circuit 300 includes thin film transistors (TFT's) T1A and T2A, capacitors C1A and C2A, and an emissive load 302. In this embodiment, the load 302 is an OLED.

TFT T1A is conductively coupled to a data line 304 and to a select line 306. Specifically, data line 304 is conductively coupled to drain electrode (D) of TFT T1A, and select line 106 is conductively coupled to gate electrode (G) of TFT T1A. The source electrode (S) of TFT T1A is conductively coupled to electrodes 307, 308 of capacitors C1A and C2A, respectively.

TFT T2A is capacitively coupled to TFT T1A. In this embodiment, the capacitive coupling is facilitated by electrode 309 of capacitor C1A being conductively coupled to gate electrode (G) of TFT T2A, and electrode 310 of capacitor C2A being conductively coupled to a capacitor communication line 312. Notably, circuit 300 lacks a via for electrically connecting a data signal, which is provided by data line 304, to TFT T2.

In operation, emissive load 302 is driven responsive to the data signal and the select signal provided by the data and select lines, respectively. Specifically, during the programming phase of each frame cycle, data is transferred to the circuit by the data line as enabled by the select signal to TFT T1. The transferred data is stored by capacitor C2, which functions as a hold capacitor.

By connecting the bottom electrode 310 of the C2 capacitor directly to a separate bus line (312), the capacitance of C2 can be made 4 times larger for the same plan area (thickness divided by two, area increased by a factor of two). Also, capacitor communication line 312 can be toggled negative immediately prior to programming to mitigate bias induced threshold shift.

It should be emphasized that the above-described embodiments are merely possible examples of implementations set forth for a clear understanding of the principles of this disclosure. Many variations and modifications may be made to the above-described embodiments without departing substantially from the spirit and principles of the disclosure. Notably, various circuit configurations other than those depicted can be used in other embodiments, such as by varying component connectivity. By way of example, the power (V_{dd}) and emissive loads could be either cathode- or anode-connected, for example. All such modifications and variations are intended to be included herein within the scope of this disclosure and protected by the accompanying claims.

1. A pixel circuit comprising:
a data line operative to carry a data signal;
a select line operative to carry a select signal;
a first thin film transistor (TFT) conductively coupled to the data line and to the select line; and
a second TFT capacitively coupled to the first TFT, the second TFT being operative to drive an emissive load responsive to the data signal and the select signal;
wherein the data signal is provided to the second TFT through capacitive coupling.

2. The pixel circuit of claim 1, wherein the emissive load is an organic light emitting diode (OLED).

3. The pixel circuit of claim 1, further comprising a first capacitor having a first electrode and a second electrode, the first electrode of the first capacitor being conductively coupled to the first TFT, the second electrode of the first capacitor being conductively coupled to the second TFT.

4. The pixel circuit of claim 3, wherein:
the first electrode of the first capacitor is conductively coupled to the source (S) of the first TFT; and
the second electrode of the first capacitor is conductively coupled to the gate (G) of the second TFT.

5. The pixel circuit of claim 3, further comprising a second capacitor having a first electrode and a second electrode, the first electrode of the second capacitor being conductively coupled to the first TFT, the second electrode of the second capacitor being conductively coupled to the second TFT.

6. The pixel circuit of claim 5, wherein:
the first electrode of the second capacitor is conductively coupled to the source of the first TFT; and
the second electrode of the second capacitor is conductively coupled to the source of the second TFT.

7. The pixel circuit of claim 1, wherein the second capacitor has an electrically floating center electrode.

8. The pixel circuit of claim 1, wherein:
the pixel circuit further comprises a communication line; and
the second capacitor has a first electrode, conductively coupled to the source of the first TFT, and a second electrode conductively coupled to the communication line; and
the communication line is operative to provide a signal to the second capacitor.

9. The pixel circuit of claim 1, wherein the signal provided by the communication line is operative to mitigate bias induced threshold shift of the second TFT.

10. A process for forming a pixel circuit, comprising:
providing a substrate;
depositing a first layer of material over the substrate;
depositing a first layer of resist over the substrate;
forming, with the first layer of resist, a 3D resist structure over the substrate; and
etching the 3D resist structure to expose a first portion of the first layer of material such that the first portion forms part of the first TFT.

11. The process of claim 10, wherein, in forming the 3D resist structure, the 3D resist structure exhibits varying vertical heights.

12. The process of claim 10, wherein, prior to depositing the first layer of resist, multiple layers of material are deposited over the substrate to form a stack of material layers.

13. The process of claim 12, wherein:
prior to the etching, the stack exhibits uniform vertical height; and
the stack, after the etching, forms the first TFT, the second TFT, the first capacitor and the second capacitor.

14. A method for controlling a pixel of an organic light emitting diode (OLED) display, comprising:
providing a pixel circuit comprising:
a data line operative to carry a data signal;
a select line operative to carry a select signal;
a first thin film transistor (TFT) conductively coupled to the data line and to the select line;
a second TFT capacitively coupled to the first TFT with a capacitive coupling; and
an emissive load conductively coupled to the second TFT; and
using the second TFT to drive the emissive load responsive to the data signal and the select signal such that, during an inactive mode of the select line, a gate (G) of the second TFT receives a voltage from the capacitive coupling to facilitate current flow through the second TFT and to the emissive load.

15. The method of claim 14, wherein, in providing the pixel circuit, the data signal is not conductively coupled to the second TFT.
